(19) United States
(12) Patent Application Publication
(10) Pub. No.: US 2020/0132843 A1
(43) Pub. Date: Apr. 30, 2020

(54) LIDAR SYSTEM AND CONTROL METHOD THEREOF

(71) Applicant: GM GLOBAL TECHNOLOGY OPERATIONS LLC, Detroit, MI (US)

(72) Inventors: Nathaniel W. Hart, Warren, MI (US); Caroline Chung, Royal Oak (US); Brian J. Hufnagel, Brighton, MI (US)

(21) Appl. No.: 16/171,444

(22) Filed: Oct. 26, 2018

(51) Int. Cl. G01S 17/89; G01S 7/481; B81B 1/00

(52) U.S. Cl. CPC G01S 17/89; B81B 2201/042; B81B 1/006; G01S 7/4817

(57) ABSTRACT

A sensor system includes an emitter configured to emit a signal having a variable emission rate. The sensor also includes an actuator configured to periodically modify a direction of the signal. The actuator has a scan rate which varies within a period. The sensor additionally includes a detector configured to receive a return signal. The sensor further includes a controller in communication with the emitter, the actuator, and the detector. The controller is configured to control the emitter to emit an output signal, and to vary an emission rate of the output signal in response to variations in the scan rate.

### INTRODUCTION

The present disclosure generally relates to vehicle perception systems, and more particularly to perception systems for autonomous vehicles.

The operation of modern vehicles is becoming more automated, i.e. able to provide driving control with less and less driver intervention. As vehicles become more automated, additional sensors such as LiDAR may be provided to facilitate autonomous behavior of the vehicle. LiDAR, which may be understood to refer to light radar or light detection and ranging, refers generally to transmitting light at a target and receiving and processing a resulting reflection.

### SUMMARY

A sensor system according to the present disclosure includes an emitter configured to emit a signal having a variable emission rate. The sensor also includes an actuator configured to periodically modify a direction of the signal. The actuator has a scan rate which varies within a period. The sensor additionally includes a detector configured to receive a return signal. The sensor further includes a controller in communication with the emitter, the actuator, and the detector. The controller is configured to control the emitter to emit an output signal, and to vary an emission rate of the output signal in response to variations in the scan rate.

In an exemplary embodiment, the controller is further configured to control the emitter to vary a power of the output signal in response to variations in the scan rate.

In an exemplary embodiment, the controller is further configured to control the detector to vary an exposure time in response to variations in the scan rate.

In an exemplary embodiment, the actuator comprises a microelectromechanical system mirror.

In an exemplary embodiment, the signal comprises a beam of light.

An automotive vehicle according to the present disclosure includes a vehicle body with a fore end, an aft end, a centerline extending from the fore end to the aft end, a port side, and a starboard side. The vehicle also includes a first sensor coupled to the body. The first sensor is configured to periodically scan a first field of view. A first scan rate of the first sensor varies within a given period. The first field of view is centered to port of the centerline. The vehicle additionally includes a second sensor coupled to the body. The second sensor is configured to periodically scan a second field of view. A second scan rate of the second sensor varies within a given period. The second field of view is centered to starboard of the centerline. The first field of view overlaps with the second field of view to define an overlap region which extends generally along the centerline. The vehicle further includes a controller in communication with the first sensor and the second sensor. The controller is configured to control the first sensor to emit a first output signal and to vary an emission rate and emission power of the first output signal in response to variations in the first scan rate, and to control the second sensor to emit a second output signal and to vary an emission rate and emission power of the second output signal in response to variations in the second scan rate.

In an exemplary embodiment, the controller is further configured to control the emitter to vary a power of the output signal in response to variations in the scan rate.

In an exemplary embodiment, the controller is further configured to control the detector to vary sensitivity in response to variations in the scan rate.

In an exemplary embodiment, actuator comprises a microelectromechanical system mirror.

In an exemplary embodiment, the signal comprises a beam of light.

In an exemplary embodiment, the vehicle additionally includes a third sensor coupled to the body. The third sensor is configured to periodically scan a third field of view. The third field of view is centered to starboard of the centerline. The third field of view overlaps with the second field of view to define a second overlap region. The second overlap region extends generally orthogonal to the centerline.

A method of controlling a sensor system according to the present disclosure includes providing the sensor with an emitter configured to emit a signal, an actuator configured to modify a direction of the signal, a detector configured to receive a return signal, and a controller in communication with the emitter, the actuator, and the detector. The method also includes controlling the emitter, via the controller, to emit an output signal having an emission rate. The method additionally includes controlling the actuator, via the controller, to periodically modify the direction of the output signal according to a scan rate. The scan rate varies within a period. The method further includes controlling the emitter, via the controller, to vary the emission rate of the output signal in response to variations in the scan rate.

In an exemplary embodiment, the method additionally includes controlling the emitter, via the controller, to vary a power of the output signal in response to variations in the scan rate. In such embodiments, controlling the emitter to power of the output signal may include controlling the emitter to increase power of the output signal in response to decreases in the scan rate.

In an exemplary embodiment, the method additionally includes controlling the detector, via the controller, to vary sensitivity in response to variations in the scan rate.

Embodiments according to the present disclosure provide a number of advantages. For example, the present disclosure provides a system and method for controlling a sensor to provide energy savings, increased range, or a combination thereof, without sacrificing resolution.

The above and other advantages and features of the present disclosure will be apparent from the following detailed description of the preferred embodiments when taken in connection with the accompanying drawings.

### BRIEF DESCRIPTION OF THE DRAWINGS

FIG. 1 is a schematic diagram of a communication system including an autonomously controlled vehicle according to an embodiment of the present disclosure;

FIG. 2 is a schematic block diagram of an automated driving system (ADS) for a vehicle according to an embodiment of the present disclosure;

FIG. 3 is a schematic block diagram of a sensor according to an embodiment of the present disclosure;

FIGS. 4A and 4B are illustrations of scan patterns as may be implemented in embodiments of the present disclosure;

FIG. 5 is an illustration of overlapping scan patterns as may be implemented in embodiments of the present disclosure;

FIG. 6 is a flowchart representation of a method of controlling a sensor according to an embodiment of the present disclosure; and

FIG. 7 is an illustration of a vehicle having sensors controlled according to an embodiment of the present disclosure.

### DETAILED DESCRIPTION

Embodiments of the present disclosure are described herein. It is to be understood, however, that the disclosed embodiments are merely examples and other embodiments can take various and alternative forms. The figures are not necessarily to scale; some features could be exaggerated or minimized to show details of particular components. Therefore, specific structural and functional details disclosed herein are not to be interpreted as limiting, but are merely representative. The various features illustrated and described with reference to any one of the figures can be combined with features illustrated in one or more other figures to produce embodiments that are not explicitly illustrated or described. The combinations of features illustrated provide representative embodiments for typical applications. Various combinations and modifications of the features consistent with the teachings of this disclosure, however, could be desired for particular applications or implementations.

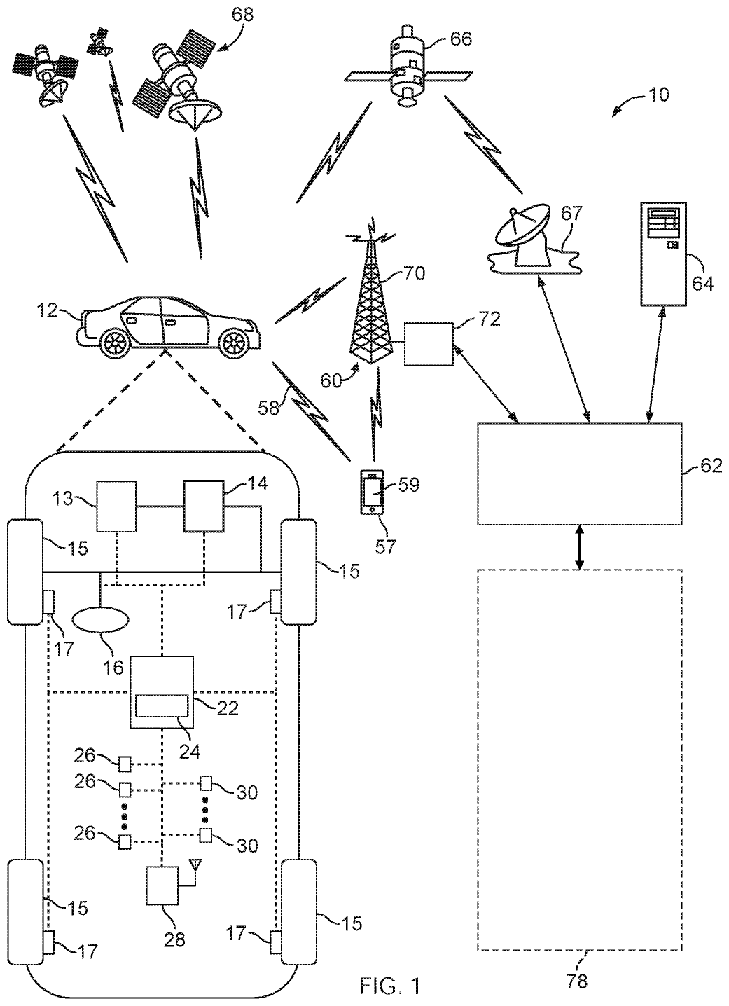

FIG. 1 schematically illustrates an operating environment that comprises a mobile vehicle communication and control system 10 for a motor vehicle 12. The communication and control system 10 for the vehicle 12 generally includes one or more wireless carrier systems 60, a land communications network 62, a computer 64, a mobile device 57 such as a smart phone, and a remote access center 78.

The vehicle 12, shown schematically in FIG. 1, is depicted in the illustrated embodiment as a passenger car, but it should be appreciated that any other vehicle including motorcycles, trucks, sport utility vehicles (SUVs), recreational vehicles (RVs), marine vessels, aircraft, etc., can also be used. The vehicle 12 includes a propulsion system 13, which may in various embodiments include an internal combustion engine, an electric machine such as a traction motor, and/or a fuel cell propulsion system.

The vehicle 12 also includes a transmission 14 configured to transmit power from the propulsion system 13 to a plurality of vehicle wheels 15 according to selectable speed ratios. According to various embodiments, the transmission 14 may include a step-ratio automatic transmission, a continuously-variable transmission, or other appropriate transmission. The vehicle 12 additionally includes wheel brakes 17 configured to provide braking torque to the vehicle wheels 15. The wheel brakes 17 may, in various embodiments, include friction brakes, a regenerative braking system such as an electric machine, and/or other appropriate braking systems.

The vehicle 12 additionally includes a steering system 16. While depicted as including a steering wheel for illustrative purposes, in some embodiments contemplated within the scope of the present disclosure, the steering system 16 may not include a steering wheel.

The vehicle 12 includes a wireless communications system 28 configured to wirelessly communicate with other vehicles (“V2V”) and/or infrastructure (“V2I”). In an exemplary embodiment, the wireless communication system 28 is configured to communicate via a dedicated short-range communications (DSRC) channel. DSRC channels refer to one-way or two-way short-range to medium-range wireless communication channels specifically designed for automotive use and a corresponding set of protocols and standards. However, wireless communications systems configured to communicate via additional or alternate wireless communications standards, such as IEEE 802.11 and cellular data communication, are also considered within the scope of the present disclosure.

The propulsion system 13, transmission 14, steering system 16, and wheel brakes 17 are in communication with or under the control of at least one controller 22. While depicted as a single unit for illustrative purposes, the controller 22 may additionally include one or more other controllers, collectively referred to as a “controller.” The controller 22 may include a microprocessor or central processing unit (CPU) in communication with various types of computer readable storage devices or media. Computer readable storage devices or media may include volatile and nonvolatile storage in read-only memory (ROM), random-access memory (RAM), and keep-alive memory (KAM), for example. KAM is a persistent or non-volatile memory that may be used to store various operating variables while the CPU is powered down. Computer-readable storage devices or media may be implemented using any of a number of known memory devices such as PROMs (programmable read-only memory), EPROMs (electrically PROM), EEPROMs (electrically erasable PROM), flash memory, or any other electric, magnetic, optical, or combination memory devices capable of storing data, some of which represent executable instructions, used by the controller 22 in controlling the vehicle.

The controller 22 includes an automated driving system (ADS) 24 for automatically controlling various actuators in the vehicle. In an exemplary embodiment, the ADS 24 is a so-called Level Three automation system. A Level Three system indicates “Conditional Automation”, referring to the driving mode-specific performance by an automated driving system of all aspects of the dynamic driving task with the expectation that the human driver will respond appropriately to a request to intervene.

Other embodiments according to the present disclosure may be implemented in conjunction with so-called Level One or Level Two automation systems. A Level One system indicates “driver assistance”, referring to the driving mode-specific execution by a driver assistance system of either steering or acceleration using information about the driving environment and with the expectation that the human driver perform all remaining aspects of the dynamic driving task. A Level Two system indicates “Partial Automation”, referring to the driving mode-specific execution by one or more driver assistance systems of both steering and acceleration using information about the driving environment and with the expectation that the human driver perform all remaining aspects of the dynamic driving task.

Still other embodiments according to the present disclosure may also be implemented in conjunction with so-called Level Four or Level Five automation systems. A Level Four system indicates “high automation”, referring to the driving mode-specific performance by an automated driving system of all aspects of the dynamic driving task, even if a human driver does not respond appropriately to a request to intervene. A Level Five system indicates “full automation”, referring to the full-time performance by an automated driving system of all aspects of the dynamic driving task under all roadway and environmental conditions that can be managed by a human driver.

In an exemplary embodiment, the ADS 24 is configured to control the propulsion system 13, transmission 14, steering system 16, and wheel brakes 17 to control vehicle acceleration, steering, and braking, respectively, without human intervention via a plurality of actuators 30 in response to inputs from a plurality of sensors 26, which may include GPS, RADAR, LIDAR, optical cameras, thermal cameras, ultrasonic sensors, and/or additional sensors as appropriate.

FIG. 1 illustrates several networked devices that can communicate with the wireless communication system 28 of the vehicle 12. One of the networked devices that can communicate with the vehicle 12 via the wireless communication system 28 is the mobile device 57. The mobile device 57 can include computer processing capability, a transceiver capable of communicating signals 58 using a short-range wireless protocol, and a visual smart phone display 59. The computer processing capability includes a microprocessor in the form of a programmable device that includes one or more instructions stored in an internal memory structure and applied to receive binary input to create binary output. In some embodiments, the mobile device 57 includes a GPS module capable of receiving signals from GPS satellites 68 and generating GPS coordinates based on those signals. In other embodiments, the mobile device 57 includes cellular communications functionality such that the mobile device 57 carries out voice and/or data communications over the wireless carrier system 60 using one or more cellular communications protocols, as are discussed herein. The visual smart phone display 59 may also include a touch-screen graphical user interface.

The wireless carrier system 60 is preferably a cellular telephone system that includes a plurality of cell towers 70 (only one shown), one or more mobile switching centers (MSCs) 72, as well as any other networking components required to connect the wireless carrier system 60 with the land communications network 62. Each cell tower 70 includes sending and receiving antennas and a base station, with the base stations from different cell towers being connected to the MSC 72 either directly or via intermediary equipment such as a base station controller. The wireless carrier system 60 can implement any suitable communications technology, including for example, analog technologies such as AMPS, or digital technologies such as CDMA (e.g., CDMA2000) or GSM/GPRS. Other cell tower/base station/MSC arrangements are possible and could be used with the wireless carrier system 60. For example, the base station and cell tower could be co-located at the same site or they could be remotely located from one another, each base station could be responsible for a single cell tower or a single base station could service various cell towers, or various base stations could be coupled to a single MSC, to name but a few of the possible arrangements.

Apart from using the wireless carrier system 60, a second wireless carrier system in the form of satellite communication can be used to provide uni-directional or bi-directional communication with the vehicle 12. This can be done using one or more communication satellites 66 and an uplink transmitting station 67. Uni-directional communication can include, for example, satellite radio services, wherein programming content (news, music, etc.) is received by the transmitting station 67, packaged for upload, and then sent to the satellite 66, which broadcasts the programming to subscribers. Bi-directional communication can include, for example, satellite telephony services using the satellite 66 to relay telephone communications between the vehicle 12 and the station 67. The satellite telephony can be utilized either in addition to or in lieu of the wireless carrier system 60.

The land network 62 may be a conventional land-based telecommunications network connected to one or more landline telephones and connects the wireless carrier system 60 to the remote access center 78. For example, the land network 62 may include a public switched telephone network (PSTN) such as that used to provide hardwired telephony, packet-switched data communications, and the Internet infrastructure. One or more segments of the land network 62 could be implemented through the use of a standard wired network, a fiber or other optical network, a cable network, power lines, other wireless networks such as wireless local area networks (WLANs), or networks providing broadband wireless access (BWA), or any combination thereof. Furthermore, the remote access center 78 need not be connected via land network 62, but could include wireless telephony equipment so that it can communicate directly with a wireless network, such as the wireless carrier system 60.

While shown in FIG. 1 as a single device, the computer 64 may include a number of computers accessible via a private or public network such as the Internet. Each computer 64 can be used for one or more purposes. In an exemplary embodiment, the computer 64 may be configured as a web server accessible by the vehicle 12 via the wireless communication system 28 and the wireless carrier 60. Other computers 64 can include, for example: a service center computer where diagnostic information and other vehicle data can be uploaded from the vehicle via the wireless communication system 28 or a third party repository to or from which vehicle data or other information is provided, whether by communicating with the vehicle 12, the remote access center 78, the mobile device 57, or some combination of these. The computer 64 can maintain a searchable database and database management system that permits entry, removal, and modification of data as well as the receipt of requests to locate data within the database. The computer 64 can also be used for providing Internet connectivity such as DNS services or as a network address server that uses DHCP or other suitable protocol to assign an IP address to the vehicle 12. The computer 64 may be in communication with at least one supplemental vehicle in addition to the vehicle 12. The vehicle 12 and any supplemental vehicles may be collectively referred to as a fleet.

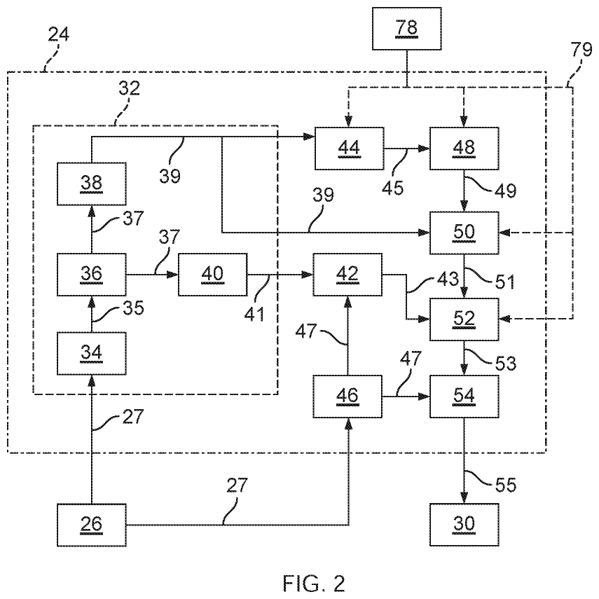

As shown in FIG. 2, the ADS 24 includes multiple distinct systems, including at least a perception system 32 for determining the presence, location, classification, and path of detected features or objects in the vicinity of the vehicle. The perception system 32 is configured to receive inputs from a variety of sensors, such as the sensors 26 illustrated in FIG. 1, and synthesize and process the sensor inputs to generate parameters used as inputs for other control algorithms of the ADS 24.

The perception system 32 includes a sensor fusion and preprocessing module 34 that processes and synthesizes sensor data 27 from the variety of sensors 26. The sensor fusion and preprocessing module 34 performs calibration of the sensor data 27, including, but not limited to, LIDAR to LIDAR calibration, camera to LIDAR calibration, LIDAR to chassis calibration, and LIDAR beam intensity calibration. The sensor fusion and preprocessing module 34 outputs preprocessed sensor output 35.

A classification and segmentation module 36 receives the preprocessed sensor output 35 and performs object classification, image classification, traffic light classification, object segmentation, ground segmentation, and object tracking processes. Object classification includes, but is not limited to, identifying and classifying objects in the surrounding environment including identification and classification of traffic signals and signs, RADAR fusion and tracking to account for the sensor's placement and field of view (FOV), and false positive rejection via LIDAR fusion to eliminate the many false positives that exist in an urban environment, such as, for example, manhole covers, bridges, overhead trees or light poles, and other obstacles with a high RADAR cross section but which do not affect the ability of the vehicle to travel along its path. Additional object classification and tracking processes performed by the classification and segmentation model 36 include, but are not limited to, freespace detection and high level tracking that fuses data from RADAR tracks, LIDAR segmentation, LIDAR classification, image classification, object shape fit models, semantic information, motion prediction, raster maps, static obstacle maps, and other sources to produce high quality object tracks. The classification and segmentation module 36 additionally performs traffic control device classification and traffic control device fusion with lane association and traffic control device behavior models. The classification and segmentation module 36 generates an object classification and segmentation output 37 that includes object identification information.

A localization and mapping module 40 uses the object classification and segmentation output 37 to calculate parameters including, but not limited to, estimates of the position and orientation of vehicle 12 in both typical and challenging driving scenarios. These challenging driving scenarios include, but are not limited to, dynamic environments with many cars (e.g., dense traffic), environments with large scale obstructions (e.g., roadwork or construction sites), hills, multi-lane roads, single lane roads, a variety of road markings and buildings or lack thereof (e.g., residential vs. business districts), and bridges and overpasses (both above and below a current road segment of the vehicle).

The localization and mapping module 40 also incorporates new data collected as a result of expanded map areas obtained via onboard mapping functions performed by the vehicle 12 during operation and mapping data “pushed” to the vehicle 12 via the wireless communication system 28. The localization and mapping module 40 updates previous map data with the new information (e.g., new lane markings, new building structures, addition or removal of constructions zones, etc.) while leaving unaffected map regions unmodified. Examples of map data that may be generated or updated include, but are not limited to, yield line categorization, lane boundary generation, lane connection, classification of minor and major roads, classification of left and right turns, and intersection lane creation. The localization and mapping module 40 generates a localization and mapping output 41 that includes the position and orientation of the vehicle 12 with respect to detected obstacles and road features.

A vehicle odometry module 46 receives data 27 from the vehicle sensors 26 and generates a vehicle odometry output 47 which includes, for example, vehicle heading and velocity information. An absolute positioning module 42 receives the localization and mapping output 41 and the vehicle odometry information 47 and generates a vehicle location output 43 that is used in separate calculations as discussed below.

An object prediction module 38 uses the object classification and segmentation output 37 to generate parameters including, but not limited to, a location of a detected obstacle relative to the vehicle, a predicted path of the detected obstacle relative to the vehicle, and a location and orientation of traffic lanes relative to the vehicle. Data on the predicted path of objects (including pedestrians, surrounding vehicles, and other moving objects) is output as an object prediction output 39 and is used in separate calculations as discussed below.

The ADS 24 also includes an observation module 44 and an interpretation module 48. The observation module 44 generates an observation output 45 received by the interpretation module 48. The observation module 44 and the interpretation module 48 allow access by the remote access center 78. The interpretation module 48 generates an interpreted output 49 that includes additional input provided by the remote access center 78, if any.

A path planning module 50 processes and synthesizes the object prediction output 39, the interpreted output 49, and additional routing information 79 received from an online database or the remote access center 78 to determine a vehicle path to be followed to maintain the vehicle on the desired route while obeying traffic laws and avoiding any detected obstacles. The path planning module 50 employs algorithms configured to avoid any detected obstacles in the vicinity of the vehicle, maintain the vehicle in a current traffic lane, and maintain the vehicle on the desired route. The path planning module 50 outputs the vehicle path information as path planning output 51. The path planning output 51 includes a commanded vehicle path based on the vehicle route, vehicle location relative to the route, location and orientation of traffic lanes, and the presence and path of any detected obstacles.

A first control module 52 processes and synthesizes the path planning output 51 and the vehicle location output 43 to generate a first control output 53. The first control module 52 also incorporates the routing information 79 provided by the remote access center 78 in the case of a remote take-over mode of operation of the vehicle.

A vehicle control module 54 receives the first control output 53 as well as velocity and heading information 47 received from vehicle odometry 46 and generates vehicle control output 55. The vehicle control output 55 includes a set of actuator commands to achieve the commanded path from the vehicle control module 54, including, but not limited to, a steering command, a shift command, a throttle command, and a brake command.

The vehicle control output 55 is communicated to actuators 30. In an exemplary embodiment, the actuators 30 include a steering control, a shifter control, a throttle control, and a brake control. The steering control may, for example, control a steering system 16 as illustrated in FIG. 1. The shifter control may, for example, control a transmission 14 as illustrated in FIG. 1. The throttle control may, for example, control a propulsion system 13 as illustrated in FIG. 1. The brake control may, for example, control wheel brakes 17 as illustrated in FIG. 1.

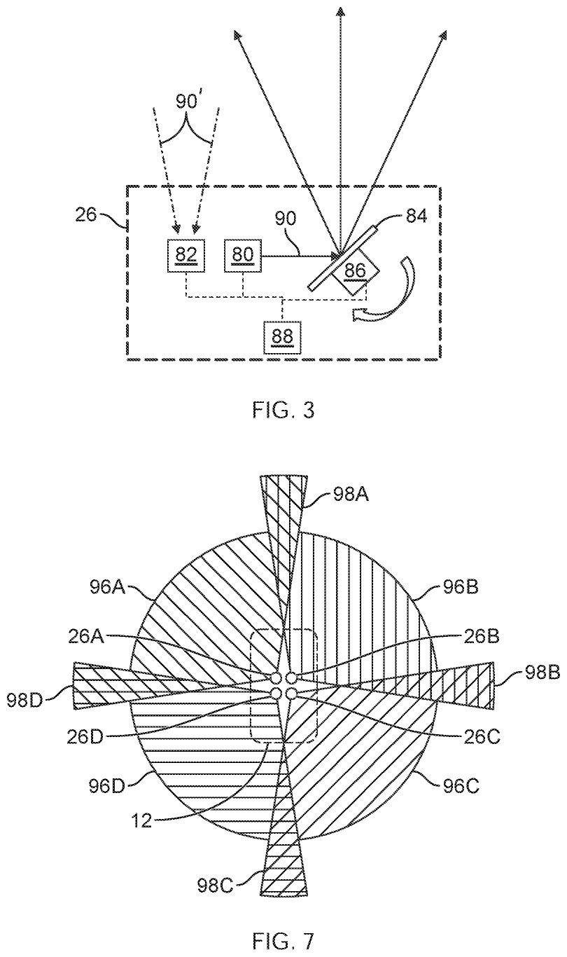

Referring now to FIG. 3, at least one of the sensors 26 is a LiDAR sensor comprising an emitter 80, a receiver 82, and a scanning mirror 84 movable by at least one actuator 86, e.g. a microelectromechanical systems (MEMS) mirror, galvanometer, or other laser scanner device. In various embodiments, the LiDAR sensor may be a pulsed LiDAR or a continuous wave LiDAR. The emitter 80, receiver 82, and actuator 86 are in communication with or under the control of a controller 88. The controller 88 may be embodied in the controller 22, a separate controller in communication with the controller 22, or any other suitable arrangement. The emitter 80 is configured to emit light pulses (in a pulsed LiDAR configuration) or chirps (in a continuous wave LiDAR configuration) 90 toward the scanning mirror 84. The actuator 86 is configured to move the scanning mirror 84 among a plurality of orientations relative to the emitter 80 under control of the controller 88, and thereby cause the light pulses or chirps 90 to scan across a region. Return light 90′ is received by the receiver 82 and processed by the controller 88 to measure distances to objects within the field of view of the receiver 82.

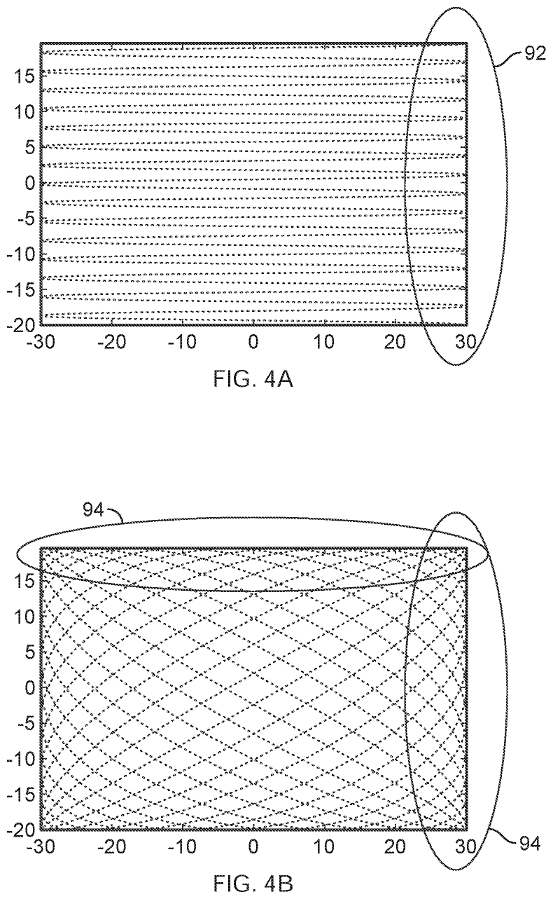

Referring now to FIG. 4A, an exemplary resonant/quasi-static scan pattern for a LiDAR sensor is illustrated. In a resonant/quasi-static scan pattern, movement of the scanning mirror along one axis is resonant while movement along the other axis is quasi-static. In the exemplary scan pattern of FIG. 4A, movement of the scanning mirror in a horizontal direction is resonant, while movement of the scanning mirror in a vertical direction is quasi-static. In the direction of resonant motion, velocity of the scanning mirror is also periodic, i.e. higher in the center of the scan pattern and lower at the edge of the scan pattern. Because the emitter is configured to emit light pulses or chirps at a constant rate, this results in a higher density of scan points at the edge of the scan pattern in the resonant direction, e.g. in the region indicated at 92.

Referring now to FIG. 4B, an exemplary resonant/resonant scan pattern for a LiDAR sensor is illustrated. In a resonant/resonant scan pattern, movement of the scanning mirror along both axes is resonant. For similar reasons as discussed above, such patterns result in a higher density of scan points at edges of the scan pattern in both directions, e.g. the regions indicated at 94.

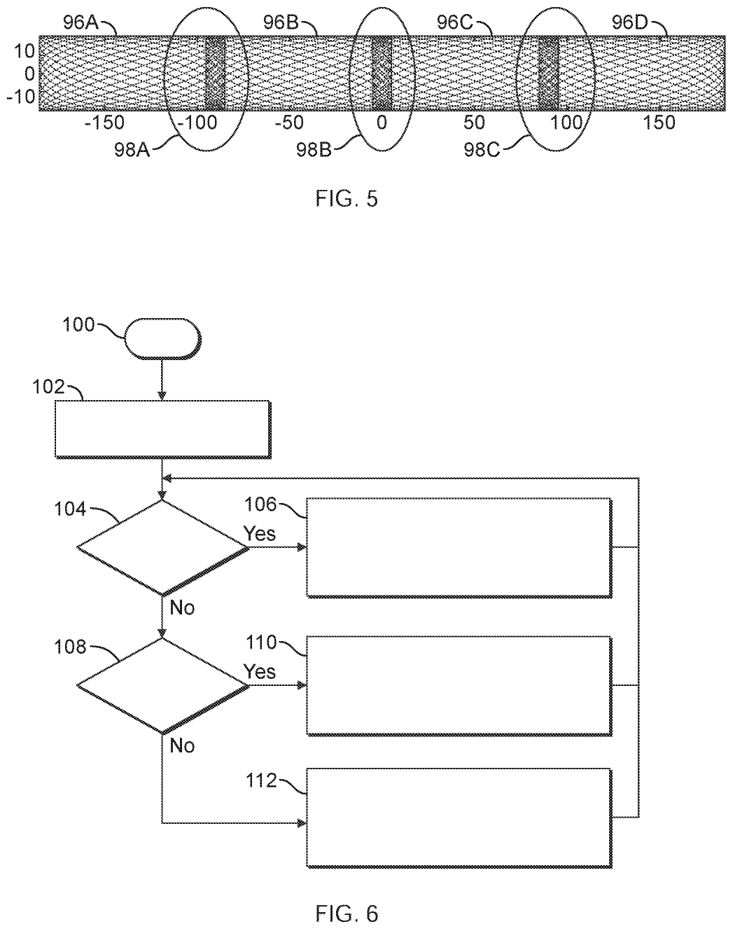

Referring now to FIG. 5, a composite scan pattern from a plurality of LiDAR assemblies is illustrated. In this illustrative example, four LiDAR assemblies are provided, each having a respective field of view covered by a respective scan pattern 96A-96D. The LiDAR assemblies are arranged such that overlap regions 98A-98C are formed at the boundaries of adjacent scan patterns 96. In such overlap regions 98, the relatively high density of scan points is further increased due to being covered by multiple respective scan patterns 96.

In known LiDAR devices, such regions of higher point density are not effectively utilized. In contrast, as will be discussed in further detail below, in LiDAR devices according to the present disclosure the emitter and/or receiver may be controlled to provide enhanced functionality in such regions.

Referring now to FIG. 6, a method of controlling a LiDAR device according to an embodiment of the present disclosure is illustrated in flowchart form. The algorithm begins at block 100.

The LiDAR sensor, e.g. arranged generally as illustrated in FIG. 3, is initialized at block 102. In an exemplary embodiment, this comprises controlling the emitter 80 to emit light pulses or chirps at a first frequency f₁ and a first power P₁. In an exemplary embodiment, f₁ is a maximum rate at which the emitter is capable of emitting pulses or chirps, which may be approximately 500,000 pulses per second. P₁ may be determined based on various considerations, including pulse rate, scan rate, and eye safety regulations. Generally speaking, such eye safety regulations dictate a permissible exposure time based on the power. In pulsed LiDAR configurations, P₁ may be approximately 100 W per pulse, and in continuous wave LiDAR configurations, P₁ may be approximately 100 mW.

A determination is made of whether a current scan rate vₜ of the mirror, e.g. an instantaneous angular velocity of the mirror, exceeds a first predefined threshold v₁, as illustrated at operation 104. In an exemplary embodiment, the threshold v₁ is selected such that the scan rate of the mirror exceeds the threshold v₁ outside of the overlap regions 98 and is less than the threshold v₁ within the overlap regions 98.

In response to the determination of operation 104 being positive, the emitter is controlled to emit light pulses or chirps at the first frequency f₁, as illustrated at block 106. In some embodiments, the power of the laser pulses or chirps is controlled to P₁, the detector exposure may be set to a default sensitivity, or both. Control then returns to operation 104.

In response to the determination of operation 104 being negative, a determination is made of whether the current scan rate vₜ of the mirror is greater than a second predefined threshold v₂ and less than the first predefined threshold v₁, as illustrated at operation 108. The second predefined threshold v₂ is greater than zero and less than the first predefined threshold v₁, and may be, for example, approximately ½ of v₁.

In response to the determination of operation 108 being positive, the emitter is controlled to emit light pulses or chirps at a second frequency f₂, as illustrated at block 110. The second frequency f₂ is less than the first frequency f₁, and may be, for example, approximately ½ of f₁. Optionally, the power of the laser pulses or chirps may be modified to P₂, where P₂ differs from P₁. In an exemplary embodiment, the magnitude of P₂ is based on eye safety regulations, and may be modified relative to P₁ based on the expected change in eye exposure duration at f₂. In pulsed LiDAR embodiments P₂ may be greater than P₁, while in continuous wave LiDAR embodiments P₂ may be less than P₁. In addition, the detector exposure sensitivity may be modified according to changes in power. Control then returns to operation 104.

In response to the determination of operation 108 being negative, the emitter is controlled to emit light pulses or chirps at a third frequency f₃, as illustrated at block 112. The third frequency f₃ is less than the second frequency f₂, and may be, for example, approximately ½ of f₂. Optionally, the power of the light pulses may be modified to P₃, where P₃ differs from P₂ and P₁. In an exemplary embodiment, the magnitude of P₃ is based on eye safety regulations, and may be modified relative to P₂ based on the expected change in eye exposure duration at f₃. In pulsed LiDAR embodiments P₃ may be greater than P₂, while in continuous wave LiDAR embodiments P₃ may be less than P₂. In addition, the detector exposure sensitivity may be modified according to changes in power. Control then returns to operation 104.

As may be seen, a control method as described above and illustrated in the exemplary embodiment of FIG. 6 decreases the frequency of light pulses in regions of high point density, thereby reducing energy consumption. In some embodiments, the power of light pulses in such regions is modified. In such embodiments, the energy consumption decrease may be reduced in exchange for increased range, while also complying with eye safety regulations.

Referring now to FIG. 7, an illustrative arrangement of LiDAR sensors according to the present disclosure is depicted. In this configuration, the vehicle 12 is provided with LiDAR sensors 26A, 26B, 26C, and 26D. The LiDAR sensor 26A has a field of view 96A. Rather than being centered to the fore of the vehicle, the field of view 96A is oriented approximately 45° to the left of the vehicle. Likewise, the LiDAR sensor 26B has a field of view 96B oriented approximately 45° to the right of the vehicle. An overlap region 98A is formed at the boundary of the field of view 96A and the field of view 96B. The overlap region 98A is thereby oriented to the fore of the vehicle. Advantageously, the increased range at the edges of the fields of view 96A, 96B is utilized to obtain increased sensing range and resolution in the direction of travel of the vehicle. Likewise, the LiDAR sensor 26C has a field of view 96C, and an overlap region 98B between the fields of view 96B, 96C is oriented generally to the passenger side of the vehicle. Furthermore, the LiDAR sensor 26D has a field of view 96D, and an overlap region 98C between the fields of view 96C, 96D is oriented generally to the aft of the vehicle, while an overlap region 98D between the fields of view 96D, 96A is oriented generally to the left of the vehicle.

The above embodiments are merely exemplary, and variations thereof are contemplated within the scope of the present disclosure. As an example, the frequency and power of the light pulses may be controlled in a finer or coarser fashion based on changes in scan rate than illustrated in FIG. 6. As another example, a greater or smaller number of LiDAR sensors may be utilized than illustrated in FIG. 7.

As may be seen, the present disclosure provides a system and method for controlling a sensor to provide energy savings, increased range, or a combination thereof, without sacrificing resolution.

While exemplary embodiments are described above, it is not intended that these embodiments describe all possible forms encompassed by the claims. The words used in the specification are words of description rather than limitation, and it is understood that various changes can be made without departing from the spirit and scope of the disclosure. As previously described, the features of various embodiments can be combined to form further exemplary aspects of the present disclosure that may not be explicitly described or illustrated. While various embodiments could have been described as providing advantages or being preferred over other embodiments or prior art implementations with respect to one or more desired characteristics, those of ordinary skill in the art recognize that one or more features or characteristics can be compromised to achieve desired overall system attributes, which depend on the specific application and implementation. These attributes can include, but are not limited to cost, strength, durability, life cycle cost, marketability, appearance, packaging, size, serviceability, weight, manufacturability, ease of assembly, etc. As such, embodiments described as less desirable than other embodiments or prior art implementations with respect to one or more characteristics are not outside the scope of the disclosure and can be desirable for particular applications.

What is claimed is:

1. A sensor system comprising:
an emitter configured to emit a signal having a variable emission rate;
an actuator configured to periodically modify a direction of the signal, the actuator having a scan rate, the scan rate varying within a period;
a detector configured to receive a return signal; and
a controller in communication with the emitter, the actuator, and the detector, the controller being configured to control the emitter to emit an output signal, and to vary an emission rate of the output signal in response to variations in the scan rate.

2. The sensor system of claim 1, wherein the controller is further configured to control the emitter to vary a power of the output signal in response to variations in the scan rate.

3. The sensor system of claim 1, wherein the controller is further configured to control the detector to vary sensitivity in response to variations in the scan rate.

4. The sensor system of claim 1, wherein the actuator comprises a microelectromechanical system mirror.

5. The sensor system of claim 1, wherein the output signal comprises a beam of light.

6. An automotive vehicle comprising:
a vehicle body with a fore end, an aft end, a centerline extending from the fore end to the aft end, a port side, and a starboard side;
a first sensor coupled to the body, the first sensor being configured to periodically scan a first field of view, a first scan rate of the first sensor varying within a given period, the first field of view being centered to port of the centerline;
a second sensor coupled to the body, the second sensor being configured to periodically scan a second field of view, a second scan rate of the second sensor varying within a given period, the second field of view being centered to starboard of the centerline, wherein the first field of view overlaps with the second field of view to define an overlap region, the overlap region extending generally along the centerline; and
a controller in communication with the first sensor and the second sensor, the controller being configured to control the first sensor to emit a first output signal and to vary an emission rate and emission power of the first output signal in response to variations in the first scan rate, and to control the second sensor to emit a second output signal and to vary an emission rate and emission power of the second output signal in response to variations in the second scan rate.

7. The vehicle of claim 6, wherein the controller is further configured to control the first sensor to vary a power of the first output signal in response to variations in the first scan rate.

8. The vehicle of claim 6, wherein the first sensor includes a first detector configured to receive a return signal, and wherein controller is further configured to control the first detector to vary sensitivity in response to variations in the first scan rate.

9. The vehicle of claim 6, wherein the first sensor includes a first actuator configured to periodically modify a direction of the first output signal, the first actuator comprising a microelectromechanical system mirror.

10. The vehicle of claim 6, wherein the first output signal comprises a beam of light.

11. The vehicle of claim 6, further comprising a third sensor coupled to the body, the third sensor being configured to periodically scan a third field of view, the third field of view being centered to starboard of the centerline, wherein the third field of view overlaps with the second field of view to define a second overlap region, the second overlap region extending generally orthogonal to the centerline.

12. A method of controlling a sensor system comprising:
providing the sensor with an emitter configured to emit a signal, an actuator configured to modify a direction of the signal, a detector configured to receive a return signal, and a controller in communication with the emitter, the actuator, and the detector;
controlling the emitter, via the controller, to emit an output signal having an emission rate;
controlling the actuator, via the controller, to periodically modify the direction of the output signal according to a scan rate, the scan rate varying within a period; and
controlling the emitter, via the controller, to vary the emission rate of the output signal in response to variations in the scan rate.

13. The method of claim 12, further comprising controlling the emitter, via the controller, to vary a power of the output signal in response to variations in the scan rate.

14. The method of claim 13, wherein controlling the emitter to power of the output signal comprises controlling the emitter to increase power of the output signal in response to decreases in the scan rate.

15. The method of claim 12, further comprising controlling the detector, via the controller, to vary sensitivity in response to variations in the scan rate.
